(19) United States
(12) Patent Application Publication
(10) Pub. No.: US 2022/0411695 A1
(43) Pub. Date: Dec. 29, 2022

(54) QUANTUM DOT, WAVELENGTH CONVERSION MATERIAL, BACKLIGHT UNIT, IMAGE DISPLAY DEVICE, AND METHOD FOR PRODUCING QUANTUM DOT

(71) Applicant: SHIN-ETSU CHEMICAL CO., LTD., Tokyo (JP)

(72) Inventors: Yoshihiro NOJIMA, Annaka-shi (JP); Shinji AOKI, Annaka-shi (JP); Kazuya TOBISHIMA, Annaka-shi (JP)

(73) Assignee: SHIN-ETSU CHEMICAL CO., LTD., Tokyo (JP)

(21) Appl. No.: 17/780,260

(22) PCT Filed: Oct. 29, 2020
(86) PCT No.: PCT/JP2020/040566

§ 371 Date: May 26, 2022

(30) Foreign Application Priority Data
Dec. 2, 2019 (JP) 2019-217782

(51) Int. Cl. C09K 11/88; B82Y 30/00; B82Y 40/00; C09K 11/56; H01L 51/50; H01L 33/50

(52) U.S. Cl. CPC C09K 11/883; B82Y 30/00; B82Y 40/00; C09K 11/565; H01L 51/502; H01L 33/501

(57) ABSTRACT

A quantum dot includes crystalline nanoparticle, wherein the quantum dot has a multi-layer structure including core particle and a plurality of layers on the core particle, and has Zn, S, Se, and Te as constituent elements, and the quantum dot has at least one quantum well structure in a radial direction from the center of the quantum dot. Therefore, quantum dots, which are crystalline nanoparticles, which do not contain harmful substances such as Cd and Pb, have excellent light emission characteristics such as half-value width at half maximum, and have high quantum efficiency.

### TECHNICAL FIELD

The present invention relates to a quantum dot comprising crystalline nanoparticle, a wavelength conversion material, a backlight unit, an image display device, and a method for producing the quantum dot.

### BACKGROUND ART

Semiconductor crystal particles with nanosized particle diameters are called quantum dots, and excitons generated upon light absorption are confined in nanosized region, so that energy level of the semiconductor crystal particles become discrete. Further, band gap changes depending on the particle diameter. Due to these effects, the fluorescence emission by quantum dots is brighter and more efficient than those by common fluorescent materials and exhibits sharp light emission.

Moreover, based on such nature that the band gap varies depending on the particle diameter, quantum dots are characterized in that the emission wavelength is controllable and are expected to be applied as a wavelength conversion material for solid-state lighting and displays. For example, by using quantum dots as a wavelength conversion material in a display, it is possible to realize a wider color range and lower power consumption than conventional fluorescent materials.

There is proposed a method for assembling quantum dots for use as a wavelength conversion material, in which quantum dots are dispersed in a resin material and a resin material containing the quantum dots is laminated with a transparent film, then the laminated film is incorporated into a backlight unit as a wavelength conversion film (Patent Document 1).

### CITATION LIST

### Patent Literature

Patent Document 1: JP 2013-544018 T
Patent Document 2: JP 2010-535262 T
Patent Document 3: WO 2013/162334 A
Patent Document 4: JP 2011-513181 T
Patent Document 5: JP 2019-81905 A

### Non Patent Literature

Non Patent Document 1: Journal of American Chemical Society 2003, Vol. 125, Issue 41, p12567-12575

### SUMMARY OF INVENTION

### Technical Problem

Those widely used as conventional quantum dots contain harmful Cd and Pb. Considering influence on the human body and the environmental load, quantum dots that do not contain these harmful substances are required.

InP based quantum dots (Patent Document 2), AgInS₂, AgInSe₂ based quantum dots (Patent Document 3), CuInS₂, CuInSe₂ based quantum dots (Patent Document 4), or the like are proposed as quantum dots that do not contain harmful substances such as Cd and Pb. However, the luminous half-value width of these quantum dots is broader than that containing Cd and Pb, and those having the same or higher characteristics have not been obtained.

To solve such a problem, Zn based quantum dots have been proposed as quantum dots which do not contain Cd or Pb, and characteristics at the same level as those of quantum dots that include Cd or Pb with a luminous half-value width of 40 nm or less have been reported (Patent Document 5). However, such current ZnTe based quantum dots have low quantum efficiency, and further improvement in quantum efficiency is required for use as a wavelength conversion material for displays or the like.

The present invention has been made to solve the above problems, and an object of the present invention is to provide quantum dots and a method for producing quantum dots, which do not contain harmful substances such as Cd and Pb, have excellent luminous characteristics such as luminous half-value width and high quantum efficiency.

### Solution to Problem

The present invention has been made to achieve the above object, and provides a quantum dot comprising crystalline nanoparticle, wherein the quantum dot has a multi-layer structure comprising core particle and a plurality of layers on the core particle, and has Zn, S, Se, and Te as constituent elements, and the quantum dot has at least one quantum well structure in a radial direction from the center of the quantum dot.

According to such a quantum dot, it becomes a quantum dot that does not contain harmful substances such as Cd and Pb, has excellent emission characteristics such as luminous half-value width and has high quantum efficiency.

At this time, the quantum dot can be a quantum dot having a superlattice structure including two or more quantum well structures in the radial direction.

As a result, the quantum dot has higher emission characteristics such as luminous half-value width and higher quantum efficiency.

At this time, the quantum dot can have the quantum well structure having a composition of ZnSₓSe₁₋ₓ/ZnTe/ZnS_{y}Se_{1-y} (0≤x≤1, 0≤y≤1) and ZnSₓSe₁₋ₓ/ZnS_{α}Se_{β}Te_{γ}/ZnS_{y}Se_{y-1} (0≤x≤1, 0≤y≤1, α+β+γ=1, 0≤α≤1, 0≤β≤1, 0≤γ≤1).

As a result, the quantum dots are excellent in emission characteristics such as luminous half-value width and have higher quantum efficiency.

At this time, the quantum dot can have the quantum well structure having a composition of ZnSₓSe₁₋ₓ/(ZnS_{α}Se_{β}Te_{γ}/ZnS_{y}Se_{1-y}/ZnS_{α}Se_{β}Te_{γ})ₙ/ZnS_{z}Se_{1-z} (0≤x≤1, 0≤y≤1, 0≤z≤1, α+β+γ=1, 0≤α≤1, 0≤β≤1, 0≤γ≤1, n:1 or more of integer) .

As a result, the quantum dots are excellent in emission characteristics such as luminous half-value width and have higher quantum efficiency.

At this time, it is possible to provide a wavelength conversion material containing the quantum dots.

This makes it possible to provide a wavelength conversion material having a desired emission wavelength, good color reproducibility, and good luminous efficiency.

At this time, it is possible to provide a backlight unit provided with the wavelength conversion material and an image display device provided with the backlight unit.

This makes it possible to provide a backlight unit or an image display device capable of converting light having an arbitrary wavelength distribution depending on the emission wavelength of the quantum dot.

At this time, a method for producing quantum dot comprising crystalline nanoparticles can be provided, the method comprising, a step of forming a core particle, a step of forming a plurality of layers on the surface of the core particle, wherein the core particle and the plurality of layers contain Zn, S, Se and Te as constituent elements, and at least one quantum well structure is formed by the core particles and the plurality of layers, or in the plurality of layers in a radial direction from the center of the quantum dots.

As a result, it is possible to produce quantum dots that do not contain harmful substances such as Cd and Pb, have excellent light emission characteristics such as luminous half-value width, and have high quantum efficiency.

### Advantageous Effects of Invention

As described above, according to the present invention, it is possible to provide a quantum dot which does not contain harmful substances such as Cd and Pb, has excellent emission characteristics such as luminous half-value width and high quantum efficiency, and a method for producing the quantum dot. Further, by forming a wavelength conversion material and an image display device using such quantum dots, it becomes possible to provide a wavelength conversion material and an image display device having high luminous efficiency and good color reproducibility.

### BRIEF DESCRIPTION OF DRAWING

FIG. 1 shows an example of a quantum dot according to the present invention.

### DESCRIPTION OF EMBODIMENTS

Hereinafter, the present invention will be described in detail, but the present invention is not limited thereto.

As described above, there has been a demand for quantum dots and methods for producing the quantum dots, which do not contain harmful substances such as Cd and Pb, have excellent emission characteristics such as luminous half-value width, and have high quantum efficiency.

As a result of diligent studies on the above mentioned problems, inventors of the present invention have found that a quantum dot comprising crystalline nanoparticle, wherein the quantum dot has a multi-layer structure comprising core particle and a plurality of layers on the core particle, and has Zn, S, Se, and Te as constituent elements, and the quantum dot has at least one quantum well structure in a radial direction from the center of the quantum dot, becomes a quantum dot that does not contain harmful substances such as Cd and Pb, has excellent emission characteristics such as luminous half-value width and has high quantum efficiency, and have completed the present invention.

Further, inventors of the present invention have found that by a method for producing a quantum dot comprising crystalline nanoparticle, the method comprising, a step of forming a core particle, a step of forming a plurality of layers on the surface of the core particle, wherein the core particle and the plurality of layers contain Zn, S, Se and Te as constituent elements, and at least one quantum well structure is formed by the core particles and the plurality of layers, or in the plurality of layers in a radial direction from the center of the quantum dots, it can produce a quantum dot does not contain harmful substances such as Cd and Pb, has excellent emission characteristics such as luminous half-value width and has high quantum efficiency, and have completed the invention.

As described above, there was a problem of improving the luminous efficiency of Zn based quantum dots. Therefore, the inventors of present invention have made extensive studies in order to solve such a problem. As a result, they have found that quantum efficiency can be improved by forming a quantum well structure in which a layer having a small bandgap is sandwiched between layers having a large bandgap in the radial direction from the center of a quantum dot (particle).

### (Quantum Dot)

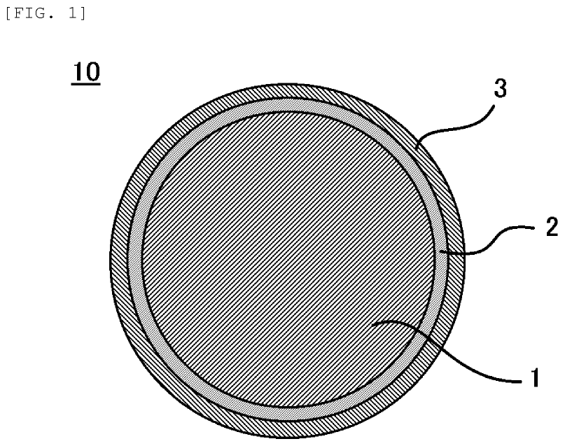

First, the quantum dot according to the present invention will be described. FIG. 1 shows an example of a quantum dot according to the present invention. The quantum dot 10 according to the present invention has a core-shell structure having a multi-layer structure comprising a core particle 1 and a plurality of layers on the core particle 1, and has Zn, S, Se, and Te as constituent elements. Further, it has a quantum well structure in which a layer 2 having a small bandgap is sandwiched between layers 3 having a large bandgap in the radial direction from the center of the quantum dot (particle). In addition, “Zn, S, Se and Te are constituent elements” means that unavoidable impurities may be contained.

The composition ratio of Zn, Te, Se, and S of the core of the quantum dot and a plurality of layers (sometimes referred to as “shell” or “shell layers”) on the core is not particularly limited as long as it forms a quantum well structure in which a layer having a small bandgap is sandwiched between layers having a large bandgap, in the radial direction from the center of the quantum dot (particle). In addition, it can be appropriately selected according to the luminous characteristics such as the target emission wavelength.

The quantum well structure and composition of the quantum dots preferably include ZnSₓSe₁₋ₓ/ZnTe/ZnS_{y}Se_{1-y} (0≤x≤1, 0≤y≤1) or ZnSₓSe₁₋ₓ/ZnS_{α}Se_{β}Te_{γ}/ZnS_{y}Se_{1-y} (0≤x≤1, 0≤y≤1, α+β+γ=1, 0≤α≤1, 0≤β≤1, 0≤γ≤1). However, the composition ratio of the ZnTe layer and the ZnS_{α}Se_{β}Te_{γ} layer is determined so that the band gap is smaller than that of the ZnSₓSe₁₋ₓ layer and the ZnS_{y}Se_{1-y} layer.

Further, it is more preferable that the quantum well structure has a composition of ZnSₓSe₁₋ₓ/(ZnS_{α}Se_{β}Te_{γ}/ZnS_{y}Se_{1-y}/ZnS_{α}Se_{β}Te_{γ})ₙ/ZnS_{z}Se_{1-z} (0≤x≤1, 0≤y≤1, 0≤z≤1, α+β+γ=1, 0≤α≤1, 0≤β≤1, 0≤γ1, n: 1, or more of integer). Such a quantum dot is excellent in emission characteristics such as a luminous half-value width and becomes a quantum dot having higher quantum efficiency.

Further, as for the quantum well structure and composition of the quantum dot, it is preferable that the structure and composition are such that two or more quantum well structures in which a layer having a small band gap is sandwiched between layers having a large band gap, are formed in the radial direction from the center of the quantum dot (particle) by adjusting the ratios of Zn, Te, Se, and S of the core and shell layers. The quantum well structure and composition of such quantum dot preferably include the one indicated by ZnSₓSe₁₋ₓ/(ZnTe/ZnSSe/ZnTe)ₙ/ZnS_{y}Se_{1-y} (0≤x≤1, 0≤y≤1, n:1 or more of integer).

Further, as for the quantum well structure and composition of the quantum dots according to the present invention, it is preferable to have a superlattice structure which is a plurality of repeated structure consisting of a quantum well structures in which a layer having a small band gap is sandwiched between layers having a large band gap in the radial direction from the center of the quantum dot (particle). As a structure having such a plurality of quantum well structures, ZnSₓSe₁₋ₓ/(ZnTe/ZnS_{y}Se_{1-y}/ZnTe)ₙ/ZnS_{z}Se_{1-z} (0≤x≤1, 0≤y≤1, 0≤z≤1, n: 1 or more of integer) can be exemplified.

The thickness of the quantum well layer in the quantum dot can be appropriately selected according to the target emission wavelength and characteristics, and in order to further improve the quantum efficiency, it is preferably 3 nm or less, and 1 nm or less is particularly preferable. Further, the quantum well structure is not particularly limited, and the band gap may be a rectangular structure or a stepped structure.

In addition to the effect of localizing excitons and improving the recombination probability by forming a quantum well structure in the quantum dot, it is expected to suppress generation of misfit dislocation caused by lattice mismatch because of the presence of a thin film layer such as a quantum well layer. For this reason, it is considered that the quantum efficiency can be improved.

Further, the size and shape of the core particles and the shell layer of the quantum dots are not particularly limited, and can be appropriately selected according to the target emission wavelength and characteristics. The average particle size of the quantum dots is preferably 20 nm or less. When the average particle size is in such a range, the quantum size effect can be obtained more stably, high luminous efficiency can be stably maintained, and band gap control by the particle size becomes easier.

A coating layer such as an organic molecule, an inorganic molecule, or a polymer may further be provided on the surface of the quantum dot, and the thickness of the coating layer can be appropriately selected depending on the intended purpose. The thickness of the coating layer is not particularly limited, but if the total particle size of the quantum dot and the coating layer is preferably 100 nm or less, the dispersibility becomes more stable and the reduction of light transmittance and aggregation can be effectively prevented.

As the coating layer, organic molecules such as stearic acid, oleic acid, palmitic acid, dimercaptosuccinic acid, oleylamine, hexadecylamine, octadecylamine, 1-dodecanethiol, trioctylphosphine oxide, triphenylphosphine oxide or the like, and polymers such as polyvinyl alcohol, polyvinylpyrrolidone, polysilsesquioxane, poly (methyl methacrylate), polyacrylonitrile, polyethylene glycol, or the like and inorganic molecules such as silica, alumina, titania, zirconia, zinc oxide, gallium oxide can be exemplified.

The particle diameter and shell layer thickness of the quantum dots are measured by measuring a particle image obtained by a transmission electron microscope (TEM), and it can be calculated from the average diameter of the major axis and the minor axis of 20 or more particles, that is, 2-axis average diameter. The shell layer thickness can be calculated as the difference between the average value of the particle diameters before and after the shell layer formation reaction. Of course, the method for measuring the average particle size is not limited to this, and other methods can be used for the measurement.

### (Method for Producing Quantum Dots)

The method for producing a quantum dot comprising crystalline nanoparticles according to the present invention, comprises a step of forming a core particle and a step of forming a plurality of layers on the surface of the core particle. Then, the core particle and the plurality of layers are formed of Zn, S, Se and Te as constituent elements, and at least one quantum well structure is formed between the core particle and the plurality of layers or among the plurality of layers in the radial direction from the center of the quantum dot.

The method for forming the quantum well structure is not particularly limited, but for example, quantum dots having a quantum well structure can be obtained by forming layers in which the band gap is changed one by one by using SILAR (Successive Ion Layer Adsorption and Reaction) method (Non Patent Document 1) in which Zn precursors and chalcogenide precursors are alternately dropped into a heated solution in which already formed core particles or core-shell particles are present.

There is also a method of forming a quantum well structure by diffusing the chalcogenide element from the adjacent layer. For example, ZnTe/ZnSeTe/ZnSe can be formed by diffusing adjacent chalcogenide elements in a quantum dot having a core-shell structure of ZnTe/ZnSe. As another form, for example, the band gap can be controlled by forming ZnSe/ZnTeSeS/ZnS in a quantum dot having a core-shell structure composed of ZnSe/ZnTe/ZnS.

In the method for forming the quantum well layer by diffusing the chalcogenide element, the heating method, the heating temperature and the treatment time can be appropriately selected depending on the desired characteristics. As a heat treatment method, a method of heating quantum dots dispersed in a high boiling point solvent with a mantle heater can be exemplified. In order to improve the composition uniformity of the diffusion layer, it is preferable to treat at a heating temperature of 300° C. or higher for 1 hour or longer.

### (Wavelength Conversion Material)

A wavelength conversion material can be obtained from the quantum dots according to the present invention. Examples of the wavelength conversion material include, but are not limited to, uses such as wavelength conversion films and color filters. It is possible to obtain a wavelength conversion material having a desired emission wavelength, good color reproducibility, and good luminous efficiency.

The method for producing the wavelength conversion material according to the present invention is not particularly limited, and can be appropriately selected depending on the intended purpose. When producing a wavelength conversion film, the quantum dots according to the present invention can be dispersed in a resin by mixing them with the resin. In this step, quantum dots dispersed in a solvent can be added and mixed with the resin and dispersed in the resin. It is also possible to disperse the quantum dots in the resin by removing the solvent and adding the quantum dots in the form of powder to the resin and kneading them. Alternatively, there is a method of polymerizing the monomers or oligomers of the constituent elements of the resin in the coexistence of quantum dots. The method of dispersing the quantum dots in the resin is not particularly limited, and can be appropriately selected depending on the purpose.

The solvent for dispersing the quantum dots is not particularly limited as long as it is compatible with the resin used. The resin material is not particularly limited, and a silicone resin, an acrylic resin, an epoxy resin, a urethane resin, or the like can be appropriately selected according to desired characteristics. It is desirable that these resins have a high transmittance in order to increase the efficiency as a wavelength conversion material, and it is particularly desirable that the transmittance is 80% or more.

Further, a substance other than quantum dots may be contained, fine particles such as silica, zirconia, alumina, and titania may be contained as a light scatterer, and an inorganic fluorescent substance or an organic fluorescent substance may be contained. As the inorganic fluorescent substance, YAG, LSN, LYSN, CASN, SCASN, KSF, CSO, β-SIALON, GYAG, LuAG and SBCA, and as the organic fluorescent substance, perylene derivatives, anthraquinone derivatives, anthracene derivatives, phthalocyanine derivatives and cyanine derivatives, dioxazine derivatives, benzooxadinone derivatives, coumarin derivatives, quinophthalone derivatives, benzoxazole derivatives, pyrarizone derivatives or the like can be mentioned.

Further, a wavelength conversion material can also be obtained by applying a resin composition in which quantum dots are dispersed in a resin to a transparent film such as PET or polyimide and curing the resin composition to form a resin layer and laminating the resin composition. For application to the transparent film, a spray method such as spray or inkjet, a spin coat, a bar coater, a doctor blade method, a gravure printing method or an offset printing method can be used. Further, the thicknesses of the resin layer and the transparent film are not particularly limited and can be appropriately selected depending on the intended use.

### (Backlight Unit, Image Display Device)

The present invention provides a backlight unit in which a wavelength conversion material such as the wavelength conversion film is installed on a light guide panel surface to which a blue LED is coupled, and an image display device including the backlight unit. Further, an image display device is provided in which the wavelength conversion material such as the wavelength conversion film is arranged between a light guide panel surface to which a blue LED is coupled and a liquid crystal display panel, for example. In such a backlight unit or an image display device, the wavelength conversion film absorbs at least a part of the blue light of the primary light as a light source and emits the secondary light having a wavelength longer than that of the primary light. It can be converted into light having an arbitrary wavelength distribution depending on the emission wavelength of the quantum dot.

### EXAMPLE

Hereinafter, the present invention will be described in more detail with reference to Examples and Comparative Examples of the present invention, but the present invention is not limited thereto.

In the evaluation of the fluorescence emission characteristics of the quantum dots produced in the Examples and Comparative Examples shown below, the luminous characteristics were measured using a quantum efficiency measurement system (QE-2100 manufactured by Otsuka Electronics) with an excitation wavelength of 450 nm. The core particle diameter was calculated by the average value of the 2-axis average diameters of 20 particles obtained by TEM observation. The shell layer thickness was calculated as the difference between the average values of the 2-axis average diameters of 20 particles before and after the reaction.

### (Solution Preparation)

79 mg of selenium powder was added to 20 mL of trioctylphosphine, and the mixture was heated and stirred at 150° C. to dissolve the selenium powder to prepare a selenium solution. 128 mg of tellurium powder was added to 20 mL of trioctylphosphine, and the mixture was heated and stirred at 150° C. to dissolve the tellurium powder to prepare a tellurium solution. 32 mg of sulfur powder was added to 20 mL of trioctylphosphine, and the mixture was heated and stirred at 150° C. to dissolve the sulfur powder to prepare sulfur solution. 460 mg of anhydrous zinc acetate and 6.9 mL of oleic acid were added to 29 mL of 1-octadecene, degassed, and then heated to 180° C. to dissolve and to prepare a zinc solution.

### Example 1

### (ZnSe Core Particle Synthesis)

20 mL of 1-octadecene and 1.2 mL of oleic acid were put into a 100 mL three-necked flask as a solvent, and degassing treatment was performed at 120° C. for 60 minutes. After degassing, the flask was filled with nitrogen gas, and the reaction was carried out with oxygen blocked state. Next, in a nitrogen atmosphere, 10 mL of the above mentioned selenium solution and 0.6 mL of 1.0 mol/L hexane solution of diethylzinc were mixed, and this mixed solution was quickly added dropwise to the flask and heated and stirred at 250° C. The ZnSe core particles were synthesized by reacting the above mixed solution at 250° C. for 30 minutes to obtain a solution containing the ZnSe core particles.

### (ZnTe Quantum Well Layer Formation)

While the solution containing ZnSe core particles was heated and stirred at 250° C., 0.5 mL of the prepared zinc solution was slowly added dropwise and heated for 40 minutes. Further, 0.5 mL of the tellurium solution was slowly added dropwise, the solution temperature was heated to 280° C., and the reaction was carried out at 280° C. for 45 minutes to obtain a solution containing ZnSe/ZnTe.

(Formation of ZnS Shell Layer) 5.5 mL of the prepared zinc solution was slowly added dropwise to the solution being heated and stirred at 280° C., and reacted at 280° C. for 30 minutes. 0.24 mL of 1-dodecanethiol was slowly added dropwise and reacted for another 30 minutes. In this way, a solution containing quantum dots having a ZnSe/ZnTe/ZnS quantum well structure (quantum dot solution) was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the luminous characteristics of the quantum dots thus obtained, the emission wavelength was 503 nm, the luminous half-value width was 25 nm, and the internal quantum efficiency was 31%. As a result of TEM analysis, ZnSe/ZnTe/ZnS had a core particle diameter of 2.8 nm and a shell layer thickness of 0.6 nm/1.8 nm, respectively.

### Example 2

### (ZnSeS Core Particle Synthesis)

20 mL of 1-octadecene and 1.2 mL of oleic acid were put into a 100 mL three-necked flask as a solvent, and degassing treatment was performed at 120° C. for 60 minutes. After degassing, the flask was filled with nitrogen gas, and the reaction was carried out with oxygen blocked state. Next, in nitrogen atmosphere, 7.6 mL of the selenium solution, 3.3 mL of the sulfur solution and 0.6 mL of 1.0 mol/L hexane solution of diethylzinc were mixed, and the mixed solution was quickly added dropwise to the flask, and heated and stirred at 270° C., and reacted at 270° C. for 30 minutes to synthesize ZnSe_{0.7}S_{0.3} core particles to obtain a solution containing ZnSe_{0.7}S_{0.3} core particles.

(ZnSeTe Quantum Well Layer Formation)

The solution containing ZnSe_{0.7}S_{0.3} core particles was heated and stirred at 250° C., and 0.5 mL of the prepared zinc solution was slowly added dropwise and heated for 40 minutes. Further, 0.3 mL of the tellurium solution and 0.1 mL of the selenium solution were mixed, and this mixed solution was slowly added dropwise, the solution temperature was heated to 280° C., and the reaction was carried out at 280° C. for 45 minutes and solution containing ZnSe_{0.7}S_{0.3}/ZnSe_{0.25}Te_{0.75} was obtained.

### (Formation of ZnSeS Shell Layer)

While this solution was heated and stirred at 280° C., 6.2 mL of the prepared zinc solution was slowly added dropwise and reacted at 280° C. for 30 minutes. Further, 3.3 mL of the selenium solution and 0.04 mL of 1-dodecanethiol were mixed, and the mixed solution was slowly added dropwise and reacted for another 45 minutes. In this way, a solution (quantum dot solution) containing quantum dots having a quantum well structure of ZnSe_{0.7}S_{0.3}/ZnSe_{0.25}Te_{0.75}/ZnSe_{0.5}S_{0.5} was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 531 nm, the luminous half-value width was 28 nm, and the internal quantum efficiency was 38%. Further, as a result of TEM analysis, ZnSe_{0.7}S_{0.3}/ZnSe_{0.25}Te_{0.75}/ZnSe_{0.5}S_{0.5} had a core particle diameter of 2.2 nm and a shell layer thickness of 0.5 nm/1.6 nm, respectively.

### Example 3

### (ZnSe Core Particle Synthesis)

20 mL of 1-octadecene and 1.2 mL of oleic acid were put into a 100 mL three-necked flask as a solvent, and degassing treatment was performed at 120° C. for 60 minutes. After degassing, the flask was filled with nitrogen gas, and the reaction was carried out with oxygen blocked state. In a nitrogen atmosphere, 10 mL of the selenium solution and 0.6 mL of 1.0 mol/L hexane solution of diethylzinc were mixed, and this mixed solution was quickly added dropwise to the flask, heated and stirred at 250° C. and reacted at 250° C. for 30 minutes to synthesize ZnSe core particles to obtain a solution containing ZnSe core particles.

### (ZnTe Quantum Well Layer Formation)

While the solution containing ZnSe core particles was heated and stirred at 250° C., 0.5 mL of the prepared zinc solution was slowly added dropwise and heated for 30 minutes. Further, 0.5 mL of the tellurium solution was slowly added dropwise, the solution temperature was heated to 260° C., and the reaction was carried out at 260° C. for 45 minutes. In this way, a solution containing ZnSe/ZnTe core-shell quantum dots was obtained.

### (Formation of ZnSe Shell Layer)

While the solution containing ZnSe/ZnTe core-shell particles was heated and stirred at 270° C., 0.5 mL of the prepared zinc solution was slowly added dropwise and reacted at 270° C. for 30 minutes. 0.5 mL of the selenium solution was slowly added dropwise and reacted for another 30 minutes. In this way, a solution containing quantum dots having a ZnSe/ZnTe/ZnSe structure was obtained.

### (ZnTe Quantum Well Layer Formation)

While the solution containing quantum dots having a ZnSe/ZnTe/ZnSe structure was heated and stirred at 270° C., 0.5 mL of the prepared zinc solution was slowly added dropwise and heated for 40 minutes. Further, 0.4 mL of the tellurium solution was slowly added dropwise the solution temperature was heated to 280° C., and the reaction was carried out at 280° C. for 30 minutes. In this way, a solution containing quantum dots having a structure of ZnSe/ZnTe/ZnSe/ZnTe was obtained.

### (Formation of ZnS Shell Layer)

While the solution containing ZnSe/ZnTe/ZnSe/ZnTe core-shell particles was heated and stirred at 280° C., 5.5 mL of the prepared zinc solution was slowly added dropwise and reacted at 280° C. for 30 minutes. 0.2 mL of 1-dodecanethiol was slowly added dropwise and reacted for another 45 minutes. In this way, a solution (quantum dot solution) containing quantum dots having two quantum well structures of ZnSe/ZnTe/ZnSe/ZnTe/ZnS was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 520 nm, the luminous half-value width was 30 nm, and the internal quantum efficiency was 49%. Further, as a result of TEM analysis, ZnSe/ZnTe/ZnSe/ZnTe/ZnS had a core particle diameter of 2.5 nm and a shell layer thickness of 0.5 nm/0.7 nm/0.4 nm/1.4 nm, respectively.

### Example 4

### (ZnSeS Core Particle Synthesis)

20 mL of 1-octadecene and 1.2 mL of oleic acid were put into a 100 mL three-necked flask as a solvent, and degassing treatment was performed at 120° C. for 60 minutes. After degassing, the flask was filled with nitrogen gas, and the reaction was carried out with oxygen blocked state. In a nitrogen atmosphere, 7.6 mL of the selenium solution, 3.3 mL of the sulfur solution and 0.6 mL of 1.0 mol/L hexane solution of diethylzinc were mixed, and the mixed solution was quickly added dropwise to a flask heated and stirred at 270° C. Then, the mixture was reacted at 270° C. for 30 minutes to synthesize ZnSe_{0.67}S_{0.33} core particles to obtain a solution containing ZnSe_{0.67}S_{0.33} core particles.

### (ZnSSeTe Quantum Well Layer Formation)

While the solution containing ZnSe_{0.67}S_{0.33} core particles was heated and stirred at 250° C., 0.5 mL of the prepared zinc solution was slowly added dropwise and heated for 40 minutes. Further, 0.28 mL of the tellurium solution, 0.14 mL of the selenium solution and 0.05 mL of the sulfur solution were mixed, and this mixed solution was slowly added dropwise, the solution temperature was heated to 280° C., and the reaction was carried out at 280° C. for 45 minutes. In this way, a solution containing ZnSe_{0.67}S_{0.33}/ZnS_{0.1}Se_{0.3}Te_{0.6} was obtained.

### (Formation of ZnSeS Shell Layer)

While the solution containing ZnSe_{0.67}S_{0.33}/ZnS_{0.1}Se_{0.3}Te_{0.6} was heated and stirred at 280° C., 6.2 mL of the prepared zinc solution was slowly added dropwise and reacted at 280° C. for 30 minutes. Further, 3.3 mL of the selenium solution and 0.04 mL of 1-dodecanethiol were mixed, the mixed solution was slowly added dropwise, and the reaction was further carried out for 45 minutes. In this way, a solution (quantum dot solution) containing quantum dots having a quantum well structure of ZnSe_{0.67}S_{0.33}/ZnS_{0.1}Se_{0.3}Te_{0.6}/ZnSe_{0.5}S_{0.5} was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 592 nm, the luminous half-value width was 38 nm, and the internal quantum efficiency was 52%. As a result of TEM analysis, ZnSe_{0.67}S_{0.33}/ZnS_{0.1}Se_{0.3}Te_{0.6}/ZnSe_{0.5}S_{0.5} had a core particle diameter of 2.2 nm and a shell layer thickness of 0.5 nm/1.6 nm, respectively.

### Example 5

### (ZnSeS Core Particle Synthesis)

20 mL of 1-octadecene and 1.2 mL of oleic acid were put into a 100 mL three-necked flask as a solvent, and degassing treatment was performed at 120° C. for 60 minutes. After degassing, the reaction was carried out in a state where the inside of the flask was filled with nitrogen gas and oxygen was blocked. In a nitrogen atmosphere, 7.6 mL of the selenium solution, 3.3 mL of the sulfur solution and 0.6 mL of 1.0 mol/L hexane solution of diethylzinc were mixed, and this mixed solution was quickly added dropwise to the flask heated and stirred at 270° C. The reaction was carried out at 270° C. for 30 minutes to synthesize ZnSe_{0.67}S_{0.33} core particles to obtain a solution containing ZnSe_{0.67}S_{0.33} core particles.

### (ZnSeTe Quantum Well Layer Formation)

While the solution containing ZnSe_{0.67}S_{0.33} core particles was heated and stirred at 250° C., 0.4 mL of the prepared zinc solution was slowly added dropwise and heated for 40 minutes. Further, 0.3 mL of the tellurium solution and 0.1 mL of the selenium solution were mixed, and this mixed solution was slowly added dropwise, the solution temperature was heated to 280° C., and the reaction was carried out at 280° C. for 45 minutes. In this way, a solution containing ZnSe_{0.67}S_{0.33}/ZnSe_{0.25}Te_{0.75} core-shell quantum dots was obtained.

### (Formation of ZnSeS Shell Layer)

While the solution containing ZnSe_{0.67}S_{0.33}/ZnSe_{0.25}Te_{0.75} core-shell quantum dots was heated and stirred at 280° C., 0.4 mL of the prepared zinc solution was slowly added dropwise and reacted at 280° C. for 30 minutes. Further, 0.3 mL of the selenium solution and 0.1 mL of 1-dodecanethiol were mixed, and the mixed solution was slowly added dropwise and reacted for another 45 minutes. In this way, a solution containing quantum dots having a quantum well structure of ZnSe_{0.67}S_{0.33}/ZnSe_{0.25}Te_{0.75}/ZnSe_{0.6}S_{0.4} was obtained.

### (ZnSeTe Quantum Well Layer Formation)

While the solution containing quantum dots having a quantum well structure of ZnSe_{0.67}S_{0.33}/ZnSe_{0.25}Te_{0.75}/ZnSe_{0.6}S_{0.4} was heated and stirred at 250° C., 0.4 mL of the prepared zinc solution was slowly added dropwise to the mixture and heated for 40 minutes. Further, 0.3 mL of the tellurium solution and 0.1 mL of the selenium solution were mixed, and the mixed solution was slowly added dropwise, the solution temperature was heated to 280° C., and the reaction was carried out at 280° C. for 45 minutes. In this way, a solution containing ZnSe_{0.67}S_{0.33}/ZnSe_{0.25}Te_{0.75}/ZnS e_{0.6}S_{0.4} /ZnSe_{0.25}Te_{0.75} was obtained.

### (Formation of ZnSeS Shell Layer)

The solution containing ZnSe_{0.67}S_{0.33}/ZnSe_{0.25}Te_{0.75}/ZnSe_{0.6}S_{0.4}/ZnSe_{0.25}Te_{0.75} is heated and stirred at 280° C., and 6.2 mL of the prepared zinc solution is slowly added dropwise. The reaction was carried out at 280° C. for 30 minutes. Further, 3.3 mL of the selenium solution and 0.04 mL of 1-dodecanethiol were mixed, and the mixed solution was slowly added dropwise and reacted for another 45 minutes. In this way, a solution containing quantum dots having two quantum well structures of ZnSe_{0.67}S _{0.33}/ZnSe_{0.25}Te_{0.75} /ZnSe_{0.6}S_{0.4}/ZnSe_{0.25}Te_{0.75}/ZnSe_{0.5}S_{0.5} was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 538 nm, the luminous half width was 35 nm, and the internal quantum efficiency was 56%. As a result of TEM analysis, ZnSe_{0.67}S_{0.33}/ZnSe_{0.25}Te_{0.75}/ZnSe_{0.6}S_{0.4}/ZnSe_{0.25}Te_{0.75}/ZnSe_{0.5}S_{0.5} had a core particle diameter of 2.3 nm and a shell layer thickness of 0.5 nm/0.6 nm/0.3 nm/1.1 nm, respectively.

### Comparative Example 1

### (ZnTe Core Particle Formation)

20 mL of 1-octadecene and 1.2 mL of oleic acid were put into a 100 mL three-necked flask as a solvent, and degassing treatment was performed at 120° C. for 60 minutes. After degassing, the reaction was carried out in a state where the inside of the flask was filled with nitrogen gas and oxygen was blocked. In a nitrogen atmosphere, 10 mL of the telluride solution and 0.6 mL of 1.0 mol/L hexane solution of diethylzinc were mixed, and this mixed solution was quickly added dropwise to a three-necked flask heated and stirred at 270° C. for 30 minutes. The reaction was carried out to synthesize ZnTe core particles, and a solution containing ZnTe core particles was obtained.

### (Formation of ZnS Shell Layer)

The solution containing ZnTe core particles was heated to 280° C., 5.5 mL of the prepared zinc solution was slowly added dropwise, and the mixture was reacted at 280° C. for 30 minutes. 0.24 mL of 1-dodecanethiol was slowly added dropwise and reacted for another 30 minutes. In this way, a solution containing ZnTe/ZnS core-shell quantum dots (quantum dot solution) was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 501 nm, the luminous half-value width was 30 nm, and the internal quantum efficiency was 11%. Further, as a result of TEM analysis, ZnTe/ZnS each had a core particle diameter of 2.1 nm and a shell layer thickness of 1.8 nm.

### Comparative Example 2

### (ZnSeS Core Particle Synthesis)

20 mL of 1-octadecene and 1.2 mL of oleic acid were put into a 100 mL three-necked flask as a solvent, and degassing treatment was performed at 120° C. for 60 minutes. After degassing, the reaction was carried out in a state where the inside of the flask was filled with nitrogen gas and oxygen was blocked. In a nitrogen atmosphere, 7.6 mL of the selenium solution, 3.3 mL of the sulfur solution and 0.6 mL of 1.0 mol/L hexane solution of diethylzinc were mixed, and this mixed solution was quickly added dropwise to a flask heated and stirred at 270° C. Then, the mixture was reacted at 270° C. for 30 minutes to synthesize ZnSe_{0.7}S_{0.3} core particles to obtain a solution containing ZnSe_{0.7}S_{0.3} core particles.

### (Formation of ZnS Shell Layer)

While the solution containing the core particles was heated and stirred at 250° C., 1.4 mL of the prepared zinc solution was slowly added dropwise and heated for 40 minutes. Further, 1.2 mL of the sulfur solution was mixed, the mixed solution was slowly added dropwise, the solution temperature was heated to 280° C., and the reaction was carried out at 280° C. for 45 minutes to obtain a solution containing a core-shell quantum dot of ZnSe_{0.7}S_{0.3}/ZnS.

### (Formation of ZnSeS Shell Layer)

The solution containing ZnSe_{0.7}S_{0.3}/ZnS core-shell quantum dots was heated and stirred at 280° C., and 6.2 mL of the prepared zinc solution was slowly added dropwise and reacted at 280° C. for 30 minutes. Further, 3.3 mL of the selenium solution and 0.04 mL of 1-dodecanethiol were mixed, the mixed solution was slowly added dropwise, and the reaction was further carried out for 45 minutes. In this way, a solution (quantum dot solution) containing core-shell quantum dots of ZnSe_{0.7}S_{0.3}/ZnS/ZnSe_{0.5}S_{0.5} was obtained.

To the quantum dot solution after the reaction, 5 times the volume ratio of acetone was added to precipitate the quantum dots, the solution was centrifuged at 10000 rpm for 10 minutes with a centrifuge, and redispersed the recovered precipitate in toluene. The quantum dots were purified.

As a result of measuring the emission characteristics of the quantum dots thus obtained, the emission wavelength was 538 nm, the of luminous half-value width was 36 nm, and the internal quantum efficiency was 8%. Further, as a result of TEM analysis, ZnSe_{0.7}S_{0.3}/ZnS/ZnSe_{0.5}S_{0.5} had a core particle diameter of 2.3 nm and a shell layer thickness of 1.0 nm/1.6 nm, respectively.

As is clear from the results of the above Examples and Comparative Examples, it can be seen that the quantum dots according to the present invention have excellent light emission characteristics such as luminous half-value width, have high quantum efficiency, and improve the light emission efficiency.

The present invention is not limited to the above embodiment. The above-described embodiment is just examples, those substantially have the same feature and demonstrate the same functions and effects as those in the technical concept disclosed in claims of the present invention are included in the technical scope of the present invention.

1-9. (canceled)

10. A quantum dot comprising crystalline nanoparticle, wherein the quantum dot has a multi-layer structure comprising core particle and a plurality of layers on the core particle, and has Zn, S, Se, and Te as constituent elements,
and the quantum dot has at least one quantum well structure in a radial direction from the center of the quantum dot.

11. The quantum dot according to claim 10, wherein the quantum dot has a superlattice structure including two or more quantum well structures in the radial direction.

12. The quantum dot according to claim 10, wherein the quantum well structure has a composition of ZnSₓSe₁₋ₓ/ZnTe/ZnS_{y}Se_{1-y} (0≤x≤1,0≤y≤1).

13. The quantum dot according to claim 10, wherein the quantum well structure has a composition of ZnSₓSe₁₋ₓ/ZnS_{α}Se_{β}Te_{γ}/ZnS_{y}Se_{1-y} (0≤x≤1, 0≤y≤1, α+β+γ=1, 0≤α≤1, 0≤β≤1, 0≤γ≤1).

14. The quantum dot according to claim 11, wherein the quantum well structure has a composition of ZnSₓSe₁₋ₓ/(ZnS_{α}Se_{β}Te_{γ}/ZnS_{y}Se_{1-y}/ZnS_{α}Se_{β}Te_{γ})ₙ/ZnS_{z}Se_{1-z} (0≤x≤1, 0≤y≤1, 0≤z≤1, α+β+γ=1, 0≤α≤1, 0≤β≤1, 0≤γ≤1, n: 1 or more of integer).

15. A wavelength conversion material comprising the quantum dot according to claim 10.

16. A wavelength conversion material comprising the quantum dot according to claim 11.

17. A wavelength conversion material comprising the quantum dot according to claim 12.

18. A wavelength conversion material comprising the quantum dot according to claim 13.

19. A wavelength conversion material comprising the quantum dot according to claim 14.

20. A backlight unit comprising the wavelength conversion material according to claim 15.

21. An image display device including the backlight unit according to claim 20.

22. A method for producing a quantum dot comprising crystalline nanoparticle, the method comprising,
a step of forming a core particle,
a step of forming a plurality of layers on the surface of the core particle,
wherein
the core particle and the plurality of layers contain Zn, S, Se and Te as constituent elements, and
at least one quantum well structure is formed by the core particles and the plurality of layers, or in the plurality of layers in a radial direction from the center of the quantum dots.
